(19) United States
(12) Patent Application Publication
(10) Pub. No.: US 2017/0158492 A1
(43) Pub. Date: Jun. 8, 2017

(54) LASER RESEAL INCLUDING STRESS COMPENSATION LAYER

(71) Applicant: Robert Bosch GmbH, Stuttgart (DE)

(72) Inventors: Achim Breitling, Reutlingen (DE); Frank Reichenbach, Wannweil (DE); Jochen Reinmuth, Reutlingen (DE); Julia Amthor, Reutlingen (DE)

(21) Appl. No.: 15/355,798

(22) Filed: Nov. 18, 2016

(30) Foreign Application Priority Data
Dec. 8, 2015 (DE) 102015224480.6

(51) Int. Cl. B81B 7/00; B81C 1/00

(52) U.S. Cl. CPC B81B 7/0051; B81C 1/00325; B81C 2203/0145; B81B 2201/0242; B81B 2201/0235

(57) ABSTRACT

A method is described for manufacturing a micromechanical component including a substrate and including a cap, which is connected to the substrate and, together with the substrate, encloses a first cavity, a first pressure prevailing and a first gas mixture having a first chemical composition being enclosed in the first cavity. An access opening connecting the first cavity to surroundings of the micromechanical component is formed in the substrate or cap. The first pressure and/or the first chemical composition is adjusted in the first cavity. The access opening is sealed by introducing energy or heat into an absorbing part of the substrate or cap using a laser. A layer is deposited or grown on a surface of the substrate or the cap in the area of the access opening to produce a second mechanical stress, which counteracts a first mechanical stress occurring in the case of sealed access opening.

### CROSS REFERENCE

The present application claims the benefit under 35 U.S.C. §119 of German Patent Application No. DE 102015224480.6 filed on Dec. 8, 2015, which is expressly incorporated herein by reference in its entirety.

### BACKGROUND INFORMATION

In a method described in PCT Application No. WO 2015/120939 A1, when a certain internal pressure is desired in a cavity of a micromechanical component or a gas mixture having a certain chemical composition is to be enclosed in the cavity, the internal pressure or the chemical composition is frequently adjusted during capping of the micromechanical component or during the bonding process between a substrate wafer and a cap wafer. During capping, for example, a cap is connected to a substrate, whereby the cap and the substrate together enclose the cavity. By adjusting the atmosphere or the pressure and/or the chemical composition of the gas mixture present in the surroundings during capping, it is thus possible to adjust the particular internal pressure and/or the particular chemical composition in the cavity.

With the aid of the method described in PCT Application No. WO 2015/120939 A1, an internal pressure may be adjusted in a targeted way in a cavity of a micromechanical component. It is in particular possible with the aid of this method to manufacture a micromechanical component including a first cavity, a first pressure and a first chemical composition being adjustable in the first cavity, which differ from a second pressure and a second chemical composition at the time of capping.

In the method for targeted adjusting of an internal pressure in a cavity of a micromechanical component described in PCT Application No. WO 2015/120939 A1, a narrow access channel to the cavity is created in the cap or in the cap wafer, or in the substrate or in the sensor wafer. Subsequently, the cavity is flooded with the desired gas and the desired internal pressure via the access channel. Finally, the area around the access channel is locally heated with the aid of a laser, the substrate material liquefies locally and hermetically seals the access channel during solidification.

### SUMMARY

It is an object of the present invention to provide a method for manufacturing a micromechanical component which is mechanically robust and has a long service life, in a simple and cost-effective manner. It is a further object of the present invention to provide a micromechanical component which is compact, mechanically robust and has a long service life. According to the present invention, this applies, in particular, to a micromechanical component that includes one (first) cavity. With the aid of the method according to the present invention and the micromechanical component according to the present invention, it is furthermore also possible to implement a micromechanical component in which a first pressure and a first chemical composition may be adjusted in the first cavity, and a second pressure and a second chemical composition may be adjusted in a second cavity. For example, such a method for manufacturing micromechanical components is provided, for which it is advantageous if a first pressure is enclosed in a first cavity and a second pressure is enclosed in a second cavity, the first pressure being different from the second pressure. This is the case, for example, when a first sensor unit for rotation rate measurement and a second sensor unit for acceleration measurement are to be integrated into a micromechanical component.

The object may be achieved, for example, by providing, in a fourth method step, that a layer is deposited or grown on a surface of the substrate or the cap in the area of the access opening to produce a second mechanical stress, which counteracts a first mechanical stress occurring in the case of sealed access opening.

In this way, a method for manufacturing a micromechanical component is provided in a simple and cost-effective manner, using which a second mechanical stress may be provided, which counteracts a first mechanical stress, which occurs in the case of sealed access opening. Therefore, for example, with the aid of a compensation stress, which is transmitted via the layer in the area of the access opening or via a boundary layer between the layer and the area of the access opening, a first mechanical stress, which is present without layer according to the present invention, may be reduced or at least partially compensated for. Therefore, for example, a tensile stress occurring in a material area which is solidified after the third method step and/or in the remaining substrate or remaining cap adjoining the solidified material area and/or at the interfaces between the solidified material area and the remaining substrate or the remaining cap may be reduced.

Furthermore, it is less problematic using the method according to the present invention if the substrate material is only locally heated and the heated material contracts in relation to its surroundings both during solidification and also during cooling, because the first mechanical stress produced by the contraction during solidification and also during cooling is counteracted with the aid of the layer and the second mechanical stress produced by the layer or the total mechanical stress or stress distribution prevailing in the area of the access opening may be reduced. It is also less problematic that tensile stresses may arise in the closure area, because these tensile stresses may be reduced with the aid of the layer in a targeted manner. Therefore, spontaneous cracking which occurs depending on stress and material and also cracking in the event of thermal or mechanical load of the micromechanical component are less probable during the further processing or in the field.

A method for manufacturing a micromechanical component or an arrangement is thus provided, in which a seal of a channel may be produced via local melting, the method enabling a possible low tendency toward cracking in the micromechanical component.

The term “micromechanical component” is to be understood in the context of the present invention to mean that the term includes both micromechanical components as well as microelectromechanical components.

The present invention is preferably provided for a micromechanical component including a cavity or for its manufacture. However, the present invention is also provided, for example, for a micromechanical component including two cavities or including more than two, i.e., three, four, five, six or more than six, cavities.

The access opening is preferably sealed with the aid of a laser by introducing energy or heat into a part of the substrate or of the cap that absorbs this energy or this heat. In this case, energy or heat is preferably introduced chronologically in succession into the respective absorbing part of the substrate or of the cap of multiple micromechanical components, which are manufactured together, for example, on one wafer. Alternatively, however, a chronologically parallel introduction of the energy or heat into the respective absorbing part of the substrate or of the cap of multiple micromechanical components is also provided, for example, using multiple laser beams or laser devices.

Advantageous embodiments and refinements of the present invention are described herein with reference to the figures.

According to one preferred refinement, it is provided that the cap, together with the substrate, encloses a second cavity, a second pressure prevailing and a second gas mixture having a second chemical composition being enclosed in the second cavity.

According to one preferred embodiment, it is provided that the layer is deposited or grown on the surface of the substrate or the cap facing away from the first cavity. In this way, it is advantageously possible that the second mechanical stress may be introduced into the area of the access opening via the surface of the substrate or the cap facing away from the first cavity. It is therefore advantageously possible in particular that the second mechanical stress may be introduced particularly on a side of the access opening facing away from the first cavity, and therefore a particularly advantageous stress distribution is enabled in the area of the sealed access opening.

According to one preferred embodiment, it is provided that the layer is removed over the access opening to be formed or sealed and/or directly adjacent to the access opening to be formed, opened, or sealed. In this way, it is possible that the access opening may be opened and sealed again essentially independently of the layer. In particular, it is therefore advantageously possible to deposit or grow the layer on the surface before or after the first method step and also before or after the third method step. Furthermore, it is therefore also possible to enable a particularly advantageous transmission of the second stress in or via the surface, in particular not above the access opening and/or not directly adjacent to the access opening.

According to one preferred refinement, it is provided that the fourth method step is carried out chronologically before the first method step or chronologically after the third method step. In this way, it is advantageously possible to either firstly adjust the first pressure and/or the first chemical composition in the first cavity and then deposit or grow the layer or, alternatively, to first deposit or grow the layer and subsequently adjust the first pressure and/or the first chemical composition in the first cavity.

A further subject matter of the present invention is a micromechanical component having a substrate and a cap connected to the substrate and, together with the substrate, enclosing a first cavity, a first pressure prevailing and a first gas mixture having a first chemical composition being enclosed in the first cavity, the substrate or the cap including a sealed access opening, the micromechanical component including a layer deposited or grown on a surface of the substrate or the cap in the area of the access opening to produce a second mechanical stress, which counteracts a first mechanical stress occurring in the case of sealed access opening. This advantageously provides a compact, mechanically robust, and cost-effective micromechanical component having an adjusted first pressure. The aforementioned advantages of the method according to the present invention also apply correspondingly to the micromechanical component according to the present invention.

According to one preferred refinement, it is provided that the layer is situated on a surface of the substrate or the cap facing away from the first cavity. In this way, it is advantageously possible that the second mechanical stress may be introduced into the area of the access opening via the surface of the substrate or the cap facing away from the first cavity. It is therefore advantageously possible in particular that the second mechanical stress may be introduced particularly on a side of the access opening facing away from the first cavity and therefore a particularly advantageous stress distribution is enabled in the area of the sealed access opening.

According to one preferred refinement, it is provided that the first mechanical stress is essentially tensile stress and the second mechanical stress is essentially compressive stress or the first mechanical stress is essentially a compressive stress and the second mechanical stress is essentially a tensile stress. Therefore, a tensile stress may be counteracted with the aid of a compressive stress or a compressive stress may be counteracted with the aid of a tensile stress.

According to one preferred refinement, it is provided that the layer is formed as essentially ring-shaped and/or rotationally-symmetrical in relation to the access opening. The second mechanical stress may therefore be introduced particularly advantageously in the surface or via the surface into the micromechanical component. A particularly advantageous stress distribution is thus enabled in the area of the sealed access opening.

According to one preferred refinement, it is provided that the cap, together with the substrate, encloses a second cavity, a second pressure prevailing and a second gas mixture having a second chemical composition being enclosed in the second cavity. In this way a compact, mechanically robust, and cost-effective micromechanical component having an adjusted first pressure and second pressure is advantageously provided.

According to one preferred refinement, it is provided that the first pressure is lower than the second pressure, a first sensor unit for rotation rate measurement being situated in the first cavity, and a second sensor unit for acceleration measurement being situated in the second cavity. In this way, a mechanically robust micromechanical component for rotation rate measurement and acceleration measurement, having optimal operating conditions for both the first sensor unit and the second sensor unit, is advantageously provided.

### BRIEF DESCRIPTION OF THE DRAWINGS

FIG. 1 shows a micromechanical component having an open access opening according to one exemplary specific embodiment of the present invention in a schematic representation

FIG. 2 shows the micromechanical component according to FIG. 1 having a sealed access opening in a schematic representation.

FIG. 3 shows a method for manufacturing a micromechanical component according to one exemplary specific embodiment of the present invention in a schematic representation.

### DETAILED DESCRIPTION OF EXAMPLE EMBODIMENTS

Identical parts are always denoted by the same reference numerals in the various figures and are therefore generally also cited or mentioned only once.

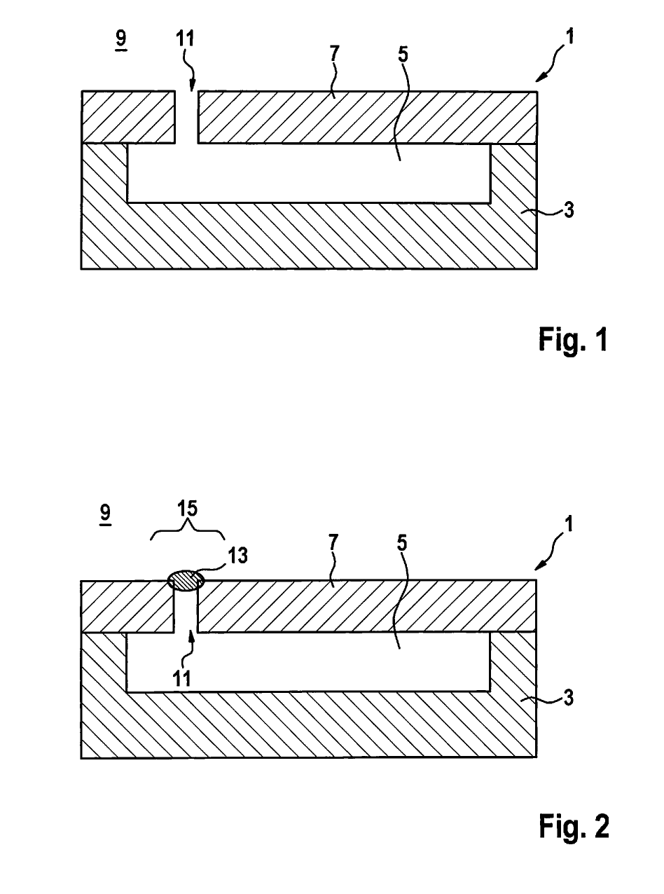

FIG. 1 and FIG. 2 show schematic representations of a micromechanical component 1 having an open access opening 11 in FIG. 1, and having a sealed access opening 11 in FIG. 2, according to one exemplary specific embodiment of the present invention. Micromechanical component 1 includes a substrate 3 and a cap 7. Substrate 3 and cap 7 are, preferably hermetically, connected to one another and together enclose a first cavity 5. For example, micromechanical component 1 is designed in such a way that substrate 3 and cap 7 additionally together enclose a second cavity. The second cavity, however, is not shown in FIG. 1 and in FIG. 2.

For example, a first pressure prevails in first cavity 5, in particular when access opening 11 is sealed, as shown in FIG. 2. Moreover, a first gas mixture having a first chemical composition is enclosed in first cavity 5. In addition, for example, a second pressure prevails in the second cavity, and a second gas mixture having a second chemical composition is enclosed in the second cavity. Access opening 11 is preferably situated in substrate 3 or in cap 7. In the present exemplary embodiment, access opening 11 is situated in cap 7 by way of example. According to the present invention, however, it may also be alternatively provided thereto that access opening 11 is situated in substrate 3.

It is provided, for example, that the first pressure in first cavity 5 is lower than the second pressure in the second cavity. It is also provided, for example, that a first micromechanical sensor unit for rotation rate measurement, which is not shown in FIG. 1 and FIG. 2, is situated in first cavity 5, and a second micromechanical sensor unit for acceleration measurement, which is not shown in FIG. 1 and FIG. 2, is situated in the second cavity.

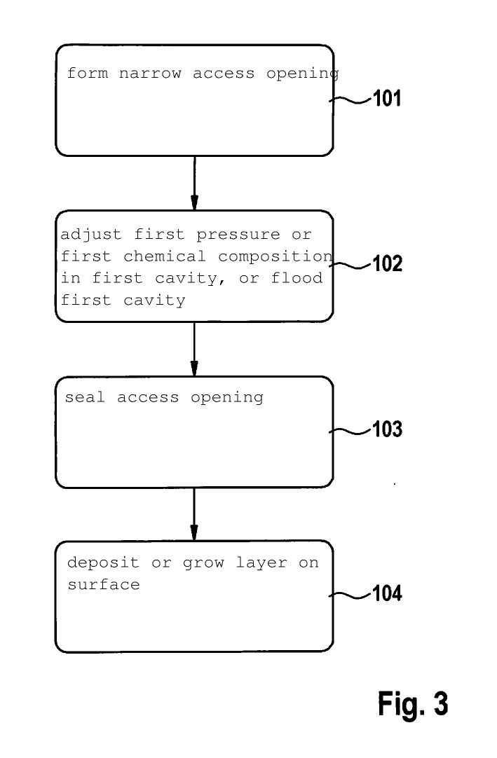

FIG. 3 shows a method for manufacturing micromechanical component 1 according to one exemplary specific embodiment of the present invention in a schematic representation. In this method,
in a first method step 101, in particular narrow access opening 11 connecting first cavity 5 to surroundings 9 of micromechanical component 1 is formed in substrate 3 or in cap 7. FIG. 1 shows micromechanical component 1 after first method step 101 by way of example. Moreover,
in a second method step 102, the first pressure and/or the first chemical composition in first cavity 5 is adjusted, or first cavity 5 is flooded with the desired gas and the desired internal pressure via the access channel. Furthermore, for example,
in a third method step 103, access opening 11 is sealed by introducing energy or heat with the aid of a laser into an absorbing part 21 of substrate 3 or cap 7. Alternatively, for example, it is also provided that
in third method step 103, the area around the access channel is preferably heated only locally by a laser, and the access channel is hermetically sealed. It is thus advantageously possible to also provide the method according to the present invention with energy sources other than with a laser for sealing access opening 11. FIG. 2 shows micromechanical component 1 after third method step 103 by way of example.

Chronologically after third method step 103, it is possible for mechanical stresses to occur in a lateral area 15, shown by way of example in FIG. 2, on a surface 19 of cap 7 facing away from cavity 5 and in the depth perpendicularly to a projection of lateral area 15 onto the surface, i.e., along access opening 11 and in the direction of first cavity 5 of micromechanical component 1. These mechanical stresses, in particular local mechanical stresses, prevail in particular on and in the vicinity of an interface between a material area 13 of cap 7, which in third method step 103 transitions into a liquid aggregate state and after third method step 103 transitions into a solid aggregate state and seals access opening 11, and a remaining area of cap 7, which remains in a solid aggregate state during third method step 103. In FIG. 2, material area 13 of cap 7 sealing access opening 11 is to be regarded only schematically or is shown only schematically, in particular with respect to its lateral extension or form, extending in particular in parallel to the surface, and in particular with respect to its expansion or configuration perpendicularly to the lateral extension, running in particular perpendicularly to the surface.

As shown by way of example in FIG. 3, in addition
in a fourth method step 104, a layer is deposited or grown on a surface of the substrate 3 or the cap 7 in the area of the access opening 11 to produce a second mechanical stress, which counteracts the first mechanical stress occurring in the case of sealed access opening 11. For this purpose, for example, the layer is deposited or grown on a surface of substrate 3 or cap 7 facing away from the first cavity 5. In addition, the layer is at least partially removed again, for example. For example, the layer is removed above access opening 11 to be formed or sealed and/or directly adjacent to access opening 11 to be formed, opened, or sealed. In other words, the additional layer is removed in the area of access channel or access opening 11. Alternatively, however, it is also provided that depending on the deposition method, the layer or the additional layer is also only applied or deposited or grown in certain selected areas of substrate 3 or cap 7. For example, plasma-induced oxide deposition using locally burning plasmas is provided for application in only selected areas. Furthermore, it is also provided, for example, that the layer or the additional layer produces or has a very high compressive stress and the layer is formed as a ring around access channel 11.

As shown by way of example in FIG. 3, fourth method step 104 is carried out chronologically after third method step 103. Alternatively, however, it is also provided that fourth method step 104 is carried out chronologically before first method step 101. For the case in which fourth method step 104 is carried out chronologically before first method step 101, it is advantageously provided, for example, that the layer or the additional layer is to be removed in an area which includes at least the area which is melted in the next step or in first method step 101 and/or in third method step 103 or the absorbing part of substrate 3 or cap 7 or material area 13. In addition, for the case in which fourth method step 104 is carried out chronologically before first method step 101, it is provided, for example, that in first method step 101, the access opening is formed in substrate 3 or in cap 7 and at least partially also in the layer or additional layer or through the layer or additional layer.

For example, it is also provided that
in fourth method step 104, the layer is applied to the substrate material or to substrate 3 or to cap 7, the layer producing compressive stress. In other words, a layer or additional layer which causes compressive stress is applied to substrate 3 or to cap 7. For example, the compressive stress counteracts a tensile stress of melted and resolidified material area 13. It is provided for this purpose, for example, that the layer produces its compressive stress as locally as possible around melted area or resolidified material area 13.

For example, it is also provided that the layer has no significant compressive stress or does not transmit it via the surface to substrate 3 or cap 7 directly after the application or growth or deposition. For example, it is also provided that the layer has a tensile stress or transmits it via the surface to substrate 3 or cap 7. It is provided in this case, for example, that the layer is chronologically conditioned after fourth method step 104 in such a way that the layer changes its stress state. For example, in this case the layer is conditioned in such a way that the layer changes its stress state in the direction of compressive stress.

Conditioning of the layer or the additional layer, for example, in such a way that the layer or additional layer changes its stress state in the direction of compressive stress, is provided as follows, for example:
for example, in fourth method step 104, a layer or PECVD layer or a layer deposited with the aid of plasma enhanced chemical vapor deposition is deposited with tensile stress, the PECVD layer being converted via a temperature step into a state having compressive stress. For example, it is provided that in the temperature step, the entire micromechanical component is warmed or heated or tempered.

For example, a layer is deposited which develops in its stress state in the direction of compressive stress during the third method step via a temperature strain or temperature treatment during heating using the laser in the area around the liquefied area or around material area 13 which is in the liquid aggregate state. This method is advantageous in two ways. On the one hand, a stress compensation layer is manufactured exactly around melted area or around material area 13 in the liquid aggregate state in a self-adjusting manner using this approach. On the other hand, higher temperatures for conditioning may be achieved locally using this method in comparison to the related art. In particular, this is advantageous if otherwise entire micromechanical component or larger areas of the micromechanical component would have to be warmed or heated or tempered alternatively in the temperature step.

For example, a layer is deposited which develops in its stress state in the direction of compressive stress during a fifth method step via a further temperature strain or temperature treatment. In other words, in this case the local conditioning of the layer or additional layer is carried out in an additional step. For example, it is provided that a laser is used for the local conditioning. It is advantageously provided in particular in this case that a laser or laser radiation or a laser pulse or a plurality of laser pulses of short wavelength, in particular having a wavelength of less than 1000 nm, and short pulse duration is used. For example, it is additionally provided that the layer or the additional layer reacts with a stress change in the direction of compressive stress due to interaction with the laser pulse or pulse, but the laser pulse is only coupled slightly into substrate 3 or cap 7, so that substrate 3 or cap 7 may not respond or react with a relaxation to the produced stress.

A micromechanical component 1 manufactured using the method according to the present invention includes, for example, a layer deposited or grown on the surface of substrate 3 or cap 7 in the area of access opening 11 to produce a second mechanical stress, which counteracts a first mechanical stress occurring in the case of sealed access opening 11. For example, for this purpose the layer is situated on a surface of substrate 3 or cap 7 facing away from first cavity 5. However, it is also possible that the layer is situated on a surface of substrate 3 or cap 7 facing toward first cavity 5. In this way, second mechanical stress may be introduced into micromechanical component 1 in particular on a side of sealed access opening 11 facing toward first cavity 5. In addition, for example, it is provided that the first mechanical stress is essentially tensile stress and the second mechanical stress is essentially compressive stress. Alternatively, it is also provided that the first mechanical stress is essentially a compressive stress and the second mechanical stress is essentially a tensile stress. According to the present invention, this means that the layer is formed in such a way that the second stress is a stress or a stress distribution which essentially counteracts the first stress or stress distribution. It is therefore also provided according to the present invention that the first stress and the second stress are at least partially a normal stress and/or a bending stress and/or a shear stress and/or a compressive stress and/or a tensile stress. Furthermore, it is also provided according to the present invention that the layer is formed, for example, essentially ring-shaped and/or rotationally-symmetrical in relation to access opening 11.

What is claimed is:

1. A method for manufacturing a micromechanical component including a substrate and including a cap, which is connected to the substrate and, together with the substrate, encloses a first cavity, a first pressure prevailing and a first gas mixture having a first chemical composition being enclosed in the first cavity, the method comprising:
in a first method step, forming, in the substrate or cape, an access opening connecting the first cavity to surroundings of the micromechanical component;
in a second method step, adjusting in the first cavity at least one of the first pressure and the first chemical composition;
in a third method step, sealing the access opening by introducing energy or heat into an absorbing part of the substrate or the cap, with the aid of a laser; and
in a fourth method step, depositing or growing a layer on a surface of the substrate or the cap in the area of the access opening to produce a second mechanical stress, which counteracts a first mechanical stress occurring in the case of sealed access opening.

2. The method as recited in claim 1, wherein the layer is deposited or grown on a surface of the substrate or the cap facing away from the first cavity.

3. The method as recited in claim 1, wherein the layer is removed at least one of: i) above the access opening to be formed or sealed, and ii) directly adjacent to the access opening to be formed, opened, or sealed.

4. The method as recited in claim 1, wherein the fourth method step is carried out chronologically before the first method step or chronologically after the third method step.

5. A micromechanical component, comprising:
a substrate;
a cap connected to the substrate and, together with the substrate, encloses a first cavity, a first pressure prevailing and a first gas mixture having a first chemical composition being enclosed in the first cavity, the substrate or the cap including a sealed access opening; and
and a layer which is deposited or grown on a surface of the substrate or the cap in the area of the access opening, to produce a second mechanical stress, which counteracts a first mechanical stress occurring in the case of sealed access opening.

6. The micromechanical component as recited in claim 5, wherein the layer is situated on the surface of the substrate or cap facing away from the first cavity.

7. The micromechanical component as recited in claim 5, wherein one of: i) the first mechanical stress is a tensile stress and the second mechanical stress is a compressive stress, or ii) the first mechanical stress is a compressive stress and the second mechanical stress is a tensile stress.

8. The micromechanical component as recited in claim 5, wherein the layer is formed as at least one of: i) ring-shaped, and ii) rotationally symmetrical in relation to the access opening.

9. The micromechanical component as recited in claim 5, wherein the cap, together with the substrate, encloses a second cavity, a second pressure prevailing and a second gas mixture having a second chemical composition being enclosed in the second cavity.

10. The micromechanical component as recited in claim 5, wherein the first pressure is lower than the second pressure, a first sensor unit for rotation rate measurement being situated in the first cavity and a second sensor unit for acceleration measurement being situated in the second cavity.
